(19) United States
(12) Patent Application Publication
(10) Pub. No.: US 2024/0029682 A1
(43) Pub. Date: Jan. 25, 2024

(54) GOA CIRCUIT, LIQUID CRYSTAL PANEL AND RELATED DRIVING METHOD

(71) Applicant: Shenzhen China Star Optoelectronics Semiconductor Display Technology Co., Ltd., Shenzhen (CN)

(72) Inventors: Yekai LIU, Shenzhen (CN); Mengya WANG, Shenzhen (CN); Peng ZHAO, Shenzhen (CN)

(21) Appl. No.: 17/423,856

(22) PCT Filed: May 31, 2021
(86) PCT No.: PCT/CN2021/097083

§ 371 Date: Jul. 17, 2021

(30) Foreign Application Priority Data
May 10, 2021 (CN) 202110503242.2

(51) Int. Cl. G09G 3/36

(52) U.S. Cl. CPC G09G 3/3677; G09G 2330/021; G09G 2310/08

(57) ABSTRACT

A gate driver on array (GOA) circuit, an LCD panel, and a driving method are proposed. The GOA circuit includes a plurality of cascaded GOA units. Each of the GOA unit includes a pull-up control circuit, a pull-up circuit, a signal transmission circuit, a pull-down circuit, a pull-down holding circuit, a first bootstrap capacitor, and a second bootstrap capacitor.

### FIELD OF THE DISCLOSURE

The present disclosure relates to a display technology, and more particularly, to a gate driver on array (GOA) circuit, a liquid crystal display (LCD) and its driving method.

### BACKGROUND

In the display field, the flat display devices, such as LCDs, have replaced cathode ray tube (CRT) displays. The LCDs have advantages of thin body, low power consumption, and no radiation and thus are widely used.

The gate driver on array (GOA) technique represents the array substrate row driving technique, which uses the array manufacturing process of the LCD panel to form the gate drivers on the thin film transistor (TFT) array substrate to achieve row-by-row scan driving method. Because the GOA technique could reduce the bonding process of the external IC, it could raise the yield and reduce the manufacturing cost. Furthermore, it could allow a display device to have a narrow border or no border.

Conventionally, because there are a huge number of TFTs in the GOA circuit, it has higher power consumption and is more difficult to have a narrow border design.

### SUMMARY

One objective of an embodiment of the present disclosure is to provide a GOA circuit to solve the above-mentioned issues of high power consumption and narrow border design difficulty.

According to an embodiment of the present disclosure, a gate driver on array (GOA) circuit is disclosed. The GOA circuit comprises a plurality of cascaded GOA units. Each of the GOA unit comprises a pull-up control circuit, a pull-up circuit, a signal transmission circuit, a pull-down circuit, a pull-down holding circuit, a first bootstrap capacitor, and a second bootstrap capacitor. In a GOA unit of an N^{th} stage and N is an integer: a first end of the pull-up control circuit receives a starting triggering signal or a stage signal of a (N−1)^{th}-stage GOA unit, and a second end of the pull-up circuit receives a starting triggering signal or a scan signal of a (N−1)^{th}-stage GOA unit; a first end of the pull-up circuit is electrically connected to the first node, and the second end of the pull-up circuit receives the clock signal or the reversed clock signal; a first end of the transmission circuit is electrically connected to the first node, and the second end of the transmission circuit receives the clock signal or the reversed clock signal; a first end of the pull-down circuit receives a scan signal of a (N+1)^{th}-stage GOA unit and a second end of the pull-down circuit is electrically connected to the first node; the first bootstrap capacitor is electrically connected between the first node and the scan signal; a first end of the pull-down holding circuit is electrically connected to a second node, a second end of the pull-down holding circuit is electrically connected to the first node and the first end of the pull-up circuit, and a third end of the pull-down holding circuit is electrically connected to a third end of the pull-up control circuit; and a first end of the second bootstrap capacitor receives the clock signal or the reversed clock signal and a second end of the second bootstrap capacitor is electrically connected to the second node.

Furthermore, the pull-up control circuit comprises a first thin film transistor (TFT), having a gate receiving the starting triggering signal or the stage signal of the (N−1)th-stage GOA unit, a source receiving the starting triggering signal or the scan signal of the (N−1)th-stage GOA unit, and a drain electrically connected to the pull-down holding circuit.

Furthermore, the pull-up circuit comprises a second TFT, having a gate electrically connected to the first node, a source receiving the clock signal or the reversed clock signal, a drain outputting a scan signal of an Nth-stage GOA unit.

Furthermore, the transmission circuit comprises a third TFT, having a gate electrically connected to the first node, a source receiving the clock signal or the reversed clock signal, a drain outputting a stage signal of the Nth-stage GOA unit.

Furthermore, the pull-down circuit comprises: a fourth TFT, having a gate receiving the scan signal of the (N+1)th-stage GOA unit, a source electrically connected to the first node, and a drain receiving a first low voltage level signal; and a fifth TFT, having a gate receiving the scan signal of the (N+1)th-stage GOA unit, a source receiving the scan signal of the Nth-stage GOA unit, and a drain receiving a second low voltage level signal.

Furthermore, the pull-down holding circuit comprises: a sixth TFT, having a gate electrically connected to the second node, a source receiving the scan signal of the Nth-stage GOA unit, and a drain receiving the second low voltage level signal; a seventh TFT, having a gate electrically connected to the second node, a source electrically connected to the first node, and a drain receiving the first low voltage level signal; an eighth TFT, having a gate electrically connected to the drain of the first TFT, a source electrically connected to the second node, and a drain receiving the first low voltage signal.

According to an embodiment of the present disclosure, an LCD panel is disclosed. The LCD panel comprises the above-mentioned GOA circuit.

According to an embodiment of the present disclosure, a driving method for driving the above-mentioned LCD panel is disclosed. When the N^{th}-stage GOA unit works, the first node corresponds to a high voltage level and the eighth TFT is turned on such that the second node is charged; and the clock signal cannot control the second node, the second bootstrap capacitor does not work and the second node corresponds to the low voltage level.

Furthermore, when the Nth-stage GOA unit does not work, the first node corresponds to a low voltage level and the eighth TFT is turned off such that the second node corresponds to a normal voltage level; and when the clock signal rises, the clock signal controls the second node to pull up a voltage level of the second node, the sixth TFT and the seven TFT are turned on such that the first node and the scan signal are maintained pulled down without being affected by the clock signal.

The present disclosure discloses a GOA circuit, an LCD panel and its driving method. By adding a bootstrap capacitor in the GOA circuit, the bootstrap capacitor could be used as an inverter, which could reduce other 9 TFTs. In this way, the power consumption is largely reduced and the size of the border is reduced. Thus, a narrow border design could be accomplished.

### BRIEF DESCRIPTION OF THE DRAWINGS

In order to explain the technical solutions in the embodiments of the present disclosure or the prior art more clearly, the drawings used in the description of the embodiments or the prior art are briefly introduced below. Obviously, the drawings in the following description are merely some embodiments of the present disclosure. For those of ordinary skill in the art, other drawings can be acquired according to the structure shown in the drawings without paying creative labor.

FIG. 1 is a diagram of a conventional GOA circuit.

FIG. 2 is a diagram of waveforms of nodes when the GOA circuit shown in FIG. 1 is in the actual operation.

FIG. 3 is a diagram of waveforms of the first high voltage level signal LC1 and the second high voltage level signal LC2 in the GOA circuit shown in FIG. 1.

FIG. 4 is a diagram of a GOA circuit according to an embodiment of the present disclosure.

FIG. 5 is a diagram of waveforms of nodes when the GOA circuit shown in FIG. 4 is in the actual operation.

### DETAILED DESCRIPTION

In addition, descriptions related to “first”, “second”, etc. in this disclosure are for descriptive purposes only, and cannot be understood as indicating or implying their relative importance or implicitly indicating the number of technical features indicated. Therefore, the features defined as “first” and “second” may explicitly or implicitly include at least one of the features. In the description of the present disclosure, the meaning of “a plurality” is at least two, for example, two, three, etc., unless it is specifically and specifically defined otherwise.

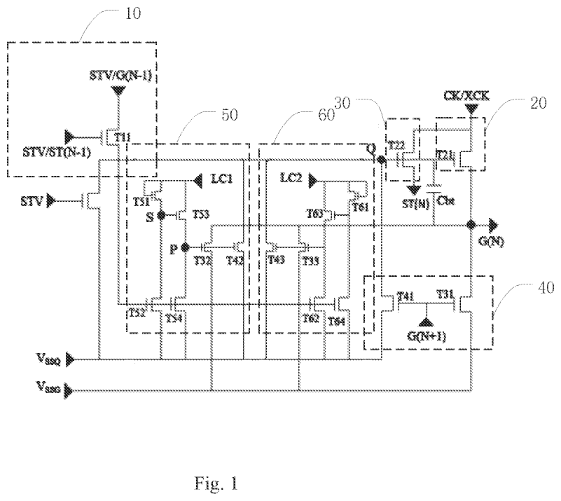

Please refer to FIG. 1. FIG. 1 is a diagram of a conventional GOA circuit. The GOA circuit comprises cascaded GOA units. Each of the GOA units comprises a pull-up control circuit 10, a pull-up circuit 20, a signal transmission circuit 30, a pull-down circuit 40, a first pull-down holding circuit 40, a second pull-down holding circuit 60 and a first bootstrap capacitor Cbt.

In the N^{th}-stage GOA unit (n is an integer):

The pull-up control circuit 10 is electrically connected the first node Q and receives the starting triggering signal STV or the stage signal ST(N−1) of the (N−1)^{th}-stage GOA unit. The pull-up control circuit 10 further receives the starting triggering signal STV or the scan signal G(N−1) of the (N−1)^{th}-stage GOA unit. The pull-up control circuit 10 is configured to output the scan signal G(N−1) of the (N−1)^{th}-stage GOA unit to the first node Q under the control of the stage signal ST(N−1) of the (N−1)^{th}-stage GOA unit.

The pull-up circuit 20 is electrically connected to the first node Q and receives the clock signal CK or the reversed clock signal XCK. The pull-up circuit 20 is configured to utilize the clock signal CK or the reversed clock signal XCK to output the scan signal G(N) under the control of the first node Q.

The signal transmission circuit 30 is electrically connected to the first node Q and receives the clock signal CK or the reversed clock signal XCK. The signal transmission circuit 30 is configured to utilize the clock signal CK or the reversed clock signal XCK to output the stage signal ST(N) under the control of the first node Q.

The pull-down circuit 40 is electrically connected to the first node Q and receives the scan signal G(N+1) of the (N+1)^{th}-stage of the GOA unit, the first low voltage level signal VSSQ, the second voltage level signal VSSG and the scan signal G(N). The pull-down circuit 40 is configured to pull down the voltage level of the first node Q to the first low voltage level VSSG under the control of the scan signal G(N+1) of the (N+1)^{th}-stage of the GOA unit and pull down the voltage level of the scan signal G(N) to the second low voltage level VSSG under the control of the scan signal G(N+1) of the (N+1)^{th}-stage of the GOA unit.

The first bootstrap capacitor Cbt is electrically connected to the first node Q. The first bootstrap capacitor Cbt is configured to pull up the voltage level of the first node Q and maintain the pulled-up voltage level during the output stage of the scan signal G(N).

The first pull-down holding circuit 50 is electrically connected to the first node and receives the scan signal G(N), the first low voltage level VSSG and the second low voltage level VSSG.

The pull-up control circuit 10 comprises a first TFT T11. The gate of the TFT T11 receives the starting triggering signal STV or the stage signal ST(N−1) of the (N−1)^{th}-stage GOA unit. The source of the TFT T11 receives starting triggering signal STV or the scan signal G(N−1) of the (N−1)^{th}-stage GOA unit. The drain of the TFT T11 is electrically connected to the first node Q.

The pull-up circuit 20 comprises a second TFT T21. The second TFT T21 has a gate electrically connected to the first node Q, a source receiving the clock signal CK or the reversed clock signal XCK, and a drain outputting the scan signal G(N).

The signal transmission circuit 30 comprises a third TFT T22. The third TFT T22 has a gate electrically connected to the first node Q, a source receiving the clock signal CK or the reversed clock signal XCK, and a drain outputting the stage signal ST(N).

The pull-down circuit 40 comprises a fourth TFT T41 and a fifth TFT T31. The fourth TFT T41 has a gate receiving the scan signal G(N+1) of the (N+1)^{th}-stage GOA unit, a source electrically connected to the first node Q, and a drain receiving the first low voltage level signal VSSG. The fifth TFT T31 has a gate receiving the scan signal G(N+1) of the (N+1)^{th}-stage GOA unit, a source receiving the scan signal G(N), and a drain receiving the second low voltage level signal VSSG.

The first end of the bootstrap capacitor Cbt is electrically connected to the first node Q and the second end of the bootstrap capacitor Cbt receives the scan signal G(N).

The first pull-down holding circuit 50 comprises a sixth TFT T32, a seventh TFT T42, and an eighth TFT T54, a ninth TFT T52, a tenth TFT T53, and an eleventh TFT T51. The sixth TFT T32 has a gate electrically connected to the second node P, a source receiving the scan signal G(N), and a drain receiving the second low voltage level signal VSSG. The seventh TFT T42 has a gate electrically connected to the second node P, a source electrically connected to the first node Q, and a drain receiving the first low voltage level signal VSSQ.

The eleventh TFT T51 has a gate and a source electrically connected to the first high voltage level signal LC1 and a drain electrically connected to the third node S. The ninth TFT T52 has a gate electrically connected to the first node Q, a source electrically connected to the third node S, and a drain receiving the first low voltage level signal VSSQ. The tenth TFT T53 has a gate electrically connected to the third node S, a source receiving the first high voltage level signal LC1, a drain electrically connected to the second node P. The eighth TFT T54 has a gate electrically connected to the first node Q, a source electrically connected to the second P, and a drain receiving the first low voltage level signal VSSQ.

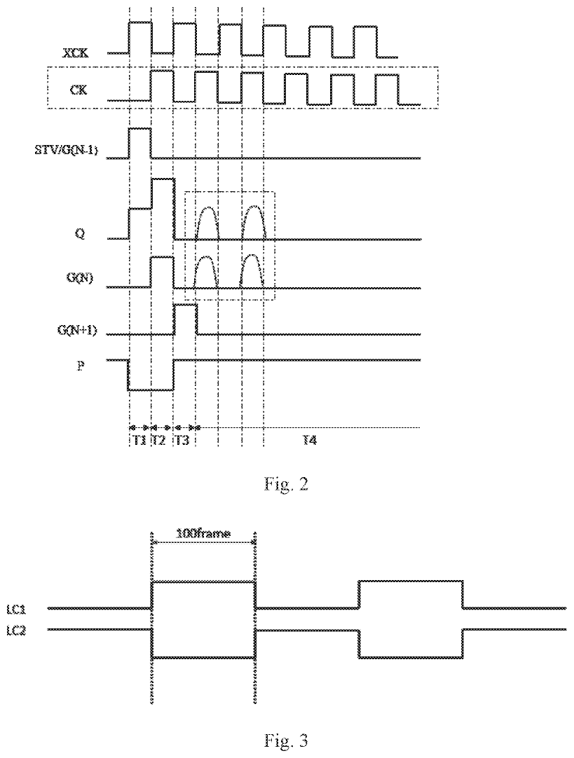

Please refer to FIG. 2. FIG. 2 is a diagram of waveforms of nodes when the GOA circuit shown in FIG. 1 is in the actual operation. Here, t1 and t2 correspond to the time periods when the current stage is working and t3 and t4 correspond to the time periods when the current stage is not working. Because the clock signal is a high frequency signal, when the current stage of GOA unit is not working, the first node Q corresponds to a constant voltage level. The clock signal CK rises to control the first node Q through the third TFT T22 and the second TFT T21 such that the voltage level of the first node Q rises. The clock signal CK falls to control the first node Q through the third TFT T22 and the second TFT T21 such that the voltage level of the first node Q falls and the output of the scan signal G(N) has multiple impulses.

The eleventh TFT T51, the ninth TFT T52, the tenth TFT T53, and the eighth TFT T54 form an inverter. The first high voltage level signal LC1 is a constant high voltage level signal and the first low voltage level signal VSSQ is a constant low voltage level signal. When the first node Q corresponds to a high voltage level, the eleventh TFT T51 and the ninth TFT T52 are well turned on. At this time, the two TFTs are equivalent to two resistors and the voltage level of the third node S is equal to the divided voltage of the ninth TFT T52. The voltage level of the third node S is not low enough so that the sixth TFT T32 and the seventh TFT T42 are not completely turned off. Thus, the voltage levels of the first node Q and the scan signal G(N) are pulled down. Therefore, the tenth TFT T53 and the eighth TFT T54 are introduced.

At this time, when the first node Q corresponds to a high voltage level, the eleventh TFT T51, the ninth TFT T52 and the eighth TFT T54 are completely turned on and the voltage level of the third node S is lower such that the tenth TFT T53 is not completely turned on. In this way, the tenth TFT T53 is equivalent to a huge resistor such that the divided voltage of the eighth TFT T54 is very low. That is, the second node P corresponds to a low voltage level such that the sixth TFT T32 and the seventh TFT T42 are turned off and the voltage level of the first node Q and the scan signal G(N) are pulled down are not pulled down.

When the first node Q corresponds to a low voltage level, the eleventh TFT T51 and the tenth TFT T53 are turned on and the ninth TFT T52 and the eighth TFT T54 are turned off. At this time, the second node P corresponds to a high voltage level. The sixth TFT T32 and the seventh TFT T42 are turned on to pull down the voltage levels of the first node Q and the scan signal G(N).

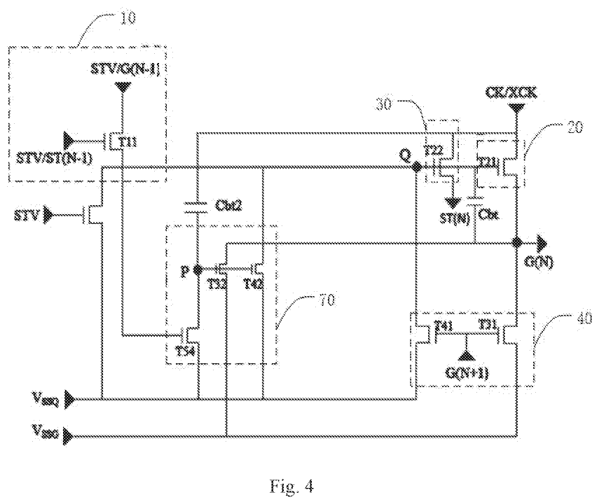

Because the first high voltage level signal LC1 is a constant high voltage level, it may hold the second node P at a high voltage level. this makes the threshold voltage Vth have a forward shift and thus the charging operation is not enough such that the first node Q and the scan signal G(N) cannot maintain its pulled-down state. Therefore, two pull-down holding modules are required and thus the second pull-down holding module 60 is introduced. The first high voltage level signal LC1 and the second high voltage level signal LC2 are both low frequency AC voltages and are reversed every frame. Please refer to FIG. 3. FIG. 3 is a diagram of waveforms of the first high voltage level signal LC1 and the second high voltage level signal LC2 in the GOA circuit shown in FIG. 1.

The second pull-down holding module 60 is configured to alleviate the forward shift of the threshold voltage Vth of the second node P. Conventionally, two identical pull-down holding modules are required. But in this way, 6 TFTs, T61, T62, T63, T64, T33, and T43 are needed.

From the above, it could be understood that the conventional pull-down holding circuit comprises 12 TFTs and occupies a huge space in the GOA layout. This is not good for the narrow border design and has high power consumption.

The present disclosure provides a GOA circuit. Please refer to FIG. 4. FIG. 4 is a diagram of a GOA circuit according to an embodiment of the present disclosure. The GOA circuit comprises a plurality of cascaded GOA units. Each of the GOA unit comprises a pull-up control circuit 10, a pull-up circuit 20, a signal transmission circuit 30, a pull-down circuit 40, a pull-down holding circuit 70, a first bootstrap capacitor Cbt and a second bootstrap capacitor Cbt2.

In the N^{th} GOA unit (n is an integer):

The first end of the pull-up control circuit 10 receives a starting triggering signal STV or a stage signal ST(N−1) of a (N−1)^{th}-stage GOA unit, and the second end of the pull-up circuit 10 receives the starting triggering signal STV or a scan signal G(N−1) of a (N−1)^{th}-stage GOA unit. The pull-up control circuit 10 is configured to output the scan signal G(N−1) of the (N−1)^{th}-stage GOA unit to the first node Q under the control of the stage signal ST(N−1) of the (N−1)^{th}-stage GOA unit.

The first end of the pull-up circuit 20 is electrically connected to the first node Q, and the second end of the pull-up circuit 20 receives the clock signal CK or the reversed clock signal XCK. The pull-up circuit 20 is configured to utilize the clock signal CK or the reversed clock signal XCK to output the scan signal G(N) under the control of the first node Q.

The first end of the transmission circuit 30 is electrically connected to the first node Q, and the second end of the transmission circuit 30 receives the clock signal CK or the reversed clock signal XCK. The transmission circuit 30 is configured to utilize the clock signal CK or the reversed clock signal XCK to output the stage signal ST(N) under the control of the first node Q.

The first end of the pull-down circuit 40 receives a scan signal G(N+1) of a (N+1)^{th}-stage GOA unit and a second end of the pull-down circuit 40 is electrically connected to the first node Q. The pull-down circuit 40 is configured to pull down the voltage level of the first node Q to the first low voltage level VSSQ under the control of the scan signal G(N+1) of the (N+1)^{th}-stage GOA unit and pull down the voltage level of the scan signal G(N) to the second low voltage level VSSG under the control of the scan signal G(N+1) of the (N+1)^{th}-stage GOA unit.

The first end of the first bootstrap capacitor Cbt is electrically connected between the first node Q and the second end of the first bootstrap capacitor Cbt receives the scan signal G(N).

The first end of the pull-down holding circuit 70 is electrically connected to a second node P, the second end of the pull-down holding circuit is electrically connected to the first node Q and the first end of the pull-up circuit 20, and the third end of the pull-down holding circuit 70 is electrically connected to the third end of the pull-up control circuit 20.

The first end of the second bootstrap capacitor Cbt2 receives the clock signal CK or the reversed clock signal XCK and the second end of the second bootstrap capacitor Cbt2 is electrically connected to the second node P.

The pull-up control circuit 10 comprises a first TFT T11. The first TFT T11 comprises a gate receiving the starting triggering signal STV or the stage signal ST(N−1) of the (N−1)^{th}-stage GOA unit, a source receiving the starting triggering signal STV or the scan signal G(N−1) of the (N−1)^{th}-stage GOA unit, and a drain electrically connected to the pull-down holding circuit 70.

The pull-up circuit 20 comprises a second TFT T21. The second TFT T21 comprises a gate electrically connected to the first node Q, a source receiving the clock signal CK or the reversed clock signal XCK, a drain outputting the scan signal G(N) of the N^{th}-stage GOA unit.

The transmission circuit 30 comprises a third TFT T22. The third TFT T22 comprises a gate electrically connected to the first node Q, a source receiving the clock signal CK or the reversed clock signal XCK, a drain outputting a stage signal ST(N) of the N^{th}-stage GOA unit.

The pull-down circuit 40 comprises a fourth TFT T41 and a fifth TFT T31. The fourth TFT T41 comprises a gate receiving the scan signal G(N+1) of the (N+1)^{th}-stage GOA unit, a source electrically connected to the first node Q, and a drain receiving the first low voltage level signal VSSQ. The fifth TFT T31 comprises a gate receiving the scan signal G(N+1) of the (N+1)^{th}-stage GOA unit, a source receiving the scan signal G(N) and a drain receiving a second low voltage level signal VSSG.

The pull-down holding circuit 70 comprises a sixth TFT T32, a seventh TFT T42 and an eighth TFT T54. The sixth TFT comprises a gate electrically connected to the second node P, a source receiving the scan signal G(N), and a drain receiving the second low voltage level signal VSSG. The seventh TFT comprises a gate electrically connected to the second node P, a source electrically connected to the first node Q, and a drain receiving the first low voltage level signal VSSQ. The eighth TFT T54 comprises a gate electrically connected to the drain of the first TFT T11, a source electrically connected to the second node P, and a drain receiving the first low voltage signal VSSQ.

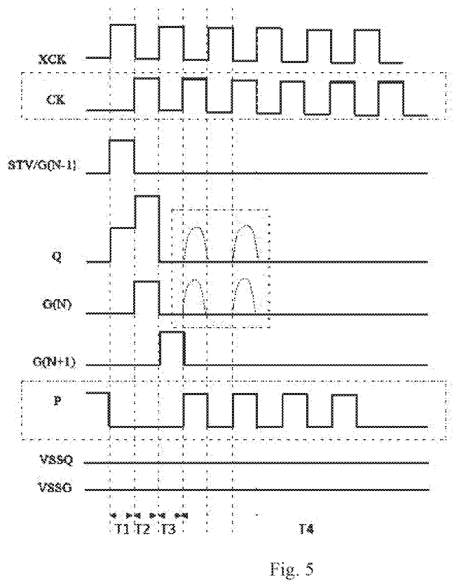

The GOA circuit of the present disclosure further includes the second bootstrap Cbt2. Please refer to FIG. 5. FIG. 5 is a diagram of waveforms of nodes when the GOA circuit shown in FIG. 4 is in the actual operation.

According to an embodiment of the present disclosure, an LCD panel is disclosed. The LCD panel comprises the above-mentioned GOA circuit. The GOA circuit has a higher temperature tolerance and has a better reliability.

The driving method for driving the above-mentioned LCD panel is as follows: When the N^{th}-stage GOA unit works, the first node Q corresponds to a high voltage level and the eighth TFT T54 is turned on such that the second node P is charged. The clock signal CK cannot control the second node P, the second bootstrap capacitor Cbt2 does not work and the second node P corresponds to the low voltage level. The sixth TFT T32 and the seventh TFT T42 do not work and have no affects on the first node Q and the third node G. Thus, the first node Q and the third node G maintain their high voltage levels.

When the N^{th}-stage GOA unit does not work, the first node Q corresponds to a low voltage level and the eighth TFT T54 is turned off such that the second node P corresponds to a normal voltage level. When the clock signal CK rises, the clock signal CK controls the second node P through the second bootstrap capacitor Cbt2 to pull up a voltage level of the second node P. The sixth TFT T32 and the seven TFT T42 are turned on to pull down the voltage levels of the first node Q and the third node G such that the first node Q and the scan signal G(N) are maintained pulled down without being affected by the clock signal CK. From the above, it could be seen that the second bootstrap capacitor Cbt2 replaces the conventional inverter.

In this embodiment, only one additional bootstrap capacitor is needed to reduce other nine thin film transistors, greatly reducing the power consumption of the GOA, and the size of the border, which is conducive to the design of narrow frame.

According to an embodiment of the present disclosure, a display device is disclosed. The display device comprises the above-mentioned LCD panel. The display device can be a mobile phone, a tablet computer, a television, a display, a notebook computer, a digital photo frame, a navigation and other products with display functions or part.

Above are embodiments of the present disclosure, which does not limit the scope of the present disclosure. Any modifications, equivalent replacements or improvements within the spirit and principles of the embodiment described above should be covered by the protected scope of the disclosure.

1. A gate driver on array (GOA) circuit, comprising a plurality of cascaded GOA units, each of the GOA unit comprising a pull-up control circuit; a pull-up circuit; a signal transmission circuit; a pull-down circuit; a pull-down holding circuit; a first bootstrap capacitor; and a second bootstrap capacitor;
wherein in a GOA unit of an N^{th} stage and N is an integer:
a first end of the pull-up control circuit receives a starting triggering signal or a stage signal of a (N−1)^{th}-stage GOA unit, and a second end of the pull-up circuit receives the starting triggering signal or a scan signal of a (N−1)^{th}-stage GOA unit;
a first end of the pull-up circuit is electrically connected to the first node, and the second end of the pull-up circuit receives a clock signal or a reversed clock signal;
a first end of the transmission circuit is electrically connected to the first node, and the second end of the transmission circuit receives the clock signal or the reversed clock signal;
a first end of the pull-down circuit receives a scan signal of a (N+1)^{th}-stage GOA unit and a second end of the pull-down circuit is electrically connected to the first node;
the first bootstrap capacitor is electrically connected between the first node and the scan signal;
a first end of the pull-down holding circuit is electrically connected to a second node, a second end of the pull-down holding circuit is electrically connected to the first node and the first end of the pull-up circuit, and a third end of the pull-down holding circuit is electrically connected to a third end of the pull-up control circuit; and
a first end of the second bootstrap capacitor receives the clock signal or the reversed clock signal and a second end of the second bootstrap capacitor is electrically connected to the second node.

2. The GOA circuit of claim 1, wherein the pull-up control circuit comprises a first thin film transistor (TFT), having a gate receiving the starting triggering signal or the stage signal of the (N−1)^{th}-stage GOA unit, a source receiving the starting triggering signal or the scan signal of the (N−1)^{th}-stage GOA unit, and a drain electrically connected to the pull-down holding circuit.

3. The GOA circuit of claim 1, wherein the pull-up circuit comprises a second TFT, having a gate electrically connected to the first node, a source receiving the clock signal or the reversed clock signal, a drain outputting a scan signal of an N^{th}-stage GOA unit.

4. The GOA circuit of claim 1, wherein the transmission circuit comprises a third TFT, having a gate electrically connected to the first node, a source receiving the clock signal or the reversed clock signal, a drain outputting a stage signal of the N^{th}-stage GOA unit.

5. The GOA circuit of claim 1, wherein the pull-down circuit comprises:
a fourth TFT, having a gate receiving the scan signal of the (N+1)^{th}-stage GOA unit, a source electrically connected to the first node, and a drain receiving a first low voltage level signal; and
a fifth TFT, having a gate receiving the scan signal of the (N+1)^{th}-stage GOA unit, a source receiving the scan signal of the N^{th}-stage GOA unit, and a drain receiving a second low voltage level signal.

6. The GOA circuit of claim 1, wherein the pull-down holding circuit comprises:
a sixth TFT, having a gate electrically connected to the second node, a source receiving the scan signal of the N^{th}-stage GOA unit, and a drain receiving the second low voltage level signal;
a seventh TFT, having a gate electrically connected to the second node, a source electrically connected to the first node, and a drain receiving the first low voltage level signal;
an eighth TFT, having a gate electrically connected to the drain of the first TFT, a source electrically connected to the second node, and a drain receiving the first low voltage signal.

7. A liquid crystal display (LCD) panel, comprising circuit a gate driver on array (GOA) circuit, the GOA circuit comprising a plurality of cascaded GOA units, each of the GOA unit comprising a pull-up control circuit; a pull-up circuit; a signal transmission circuit; a pull-down circuit; a pull-down holding circuit; a first bootstrap capacitor; and a second bootstrap capacitor;
wherein in a GOA unit of an N^{th} stage and N is an integer:
a first end of the pull-up control circuit receives a starting triggering signal or a stage signal of a (N−1)^{th}-stage GOA unit, and a second end of the pull-up circuit receives the starting triggering signal or a scan signal of a (N−1)^{th}-stage GOA unit;
a first end of the pull-up circuit is electrically connected to the first node, and the second end of the pull-up circuit receives a clock signal or a reversed clock signal;
a first end of the transmission circuit is electrically connected to the first node, and the second end of the transmission circuit receives the clock signal or the reversed clock signal;
a first end of the pull-down circuit receives a scan signal of a (N+1)^{th}-stage GOA unit and a second end of the pull-down circuit is electrically connected to the first node;
the first bootstrap capacitor is electrically connected between the first node and the scan signal;
a first end of the pull-down holding circuit is electrically connected to a second node, a second end of the pull-down holding circuit is electrically connected to the first node and the first end of the pull-up circuit, and a third end of the pull-down holding circuit is electrically connected to a third end of the pull-up control circuit; and
a first end of the second bootstrap capacitor receives the clock signal or the reversed clock signal and a second end of the second bootstrap capacitor is electrically connected to the second node.

8. The LCD panel of claim 7, wherein the pull-up control circuit comprises a first thin film transistor (TFT), having a gate receiving the starting triggering signal or the stage signal of the (N−1)th-stage GOA unit, a source receiving the starting triggering signal or the scan signal of the (N−1)th-stage GOA unit, and a drain electrically connected to the pull-down holding circuit.

9. The LCD panel of claim 8, wherein the pull-up circuit comprises a second TFT, having a gate electrically connected to the first node, a source receiving the clock signal or the reversed clock signal, a drain outputting a scan signal of an Nth-stage GOA unit.

10. The LCD panel of claim 9, wherein the transmission circuit comprises a third TFT, having a gate electrically connected to the first node, a source receiving the clock signal or the reversed clock signal, a drain outputting a stage signal of the Nth-stage GOA unit.

11. The LCD panel of claim 10, wherein the pull-down circuit comprises:
a fourth TFT, having a gate receiving the scan signal of the (N+1)th-stage GOA unit, a source electrically connected to the first node, and a drain receiving a first low voltage level signal; and
a fifth TFT, having a gate receiving the scan signal of the (N+1)th-stage GOA unit, a source receiving the scan signal of the Nth-stage GOA unit, and a drain receiving a second low voltage level signal.

12. The LCD panel of claim 11, wherein the pull-down holding circuit comprises:
a sixth TFT, having a gate electrically connected to the second node, a source receiving the scan signal of the Nth-stage GOA unit, and a drain receiving the second low voltage level signal;
a seventh TFT, having a gate electrically connected to the second node, a source electrically connected to the first node, and a drain receiving the first low voltage level signal;
an eighth TFT, having a gate electrically connected to the drain of the first TFT, a source electrically connected to the second node, and a drain receiving the first low voltage signal.

13. The LCD panel of claim 12, wherein when the N^{th}-stage GOA unit works, the first node corresponds to a high voltage level and the eighth TFT is turned on such that the second node is charged; and the clock signal cannot control the second node, the second bootstrap capacitor does not work and the second node corresponds to the low voltage level.

14. The LCD panel of claim 13, wherein when the N^{th}-stage GOA unit does not work, the first node corresponds to a low voltage level and the eighth TFT is turned off such that the second node corresponds to a normal voltage level; and when the clock signal rises, the clock signal controls the second node to pull up a voltage level of the second node, the sixth TFT and the seven TFT are turned on such that the first node and the scan signal are maintained pulled down without being affected by the clock signal.
